(19) United States
(12) Patent Application Publication
(10) Pub. No.: US 2019/0131565 A1
(43) Pub. Date: May 2, 2019

(54) DISPLAY DEVICE AND METHOD OF MANUFACTURING THE SAME

(71) Applicant: SAMSUNG DISPLAY CO., LTD., YONGIN-SI (KR)

(72) Inventors: Ohjune KWON, Hwaseong-si (KR); Seungwook KWON, Hwaseong-si (KR); Hyojeong KWON, Seoul (KR); Doohwan KIM, Yongin-si (KR); Minsang KIM, Suwon-si (KR)

(21) Appl. No.: 16/039,815

(22) Filed: Jul. 19, 2018

(30) Foreign Application Priority Data
Oct. 26, 2017 (KR) 10-2017-0139971

(51) Int. Cl. H01L 51/52; H01L 27/32

(52) U.S. Cl. CPC H01L 51/5246; H01L 27/3246; H01L 27/3258; H01L 51/0097; H01L 51/5253; H01L 51/5206; H01L 51/5221; H01L 27/3262

(57) ABSTRACT

A display device and method of manufacture may include a display panel having a first region, a second region spaced apart from the first region, and a bending region between the first region and the second region. The bending region is bent along a bending axis. A functional layer is arranged between the first region and the second region of the display panel, a core is arranged in a bending space defined by the bending region of the display panel and a side surface of the functional layer. A filler is arranged in the bending space to surround the core. A protective film may be arranged between the display panel and the functional layer. A thickness of the protective film corresponding to the bending region may be less than a thickness of a portion of the protective film corresponding to the first region or the second region.

### CROSS-REFERENCE TO RELATED APPLICATION(S)

This application claims priority under 35 USC § 119 from Korean Patent Application No. 10-2017-0139971, filed on Oct. 26, 2017 in the Korean Intellectual Property Office (KIPO), the entire disclosure of which is incorporated by reference herein.

### TECHNICAL FIELD

Embodiments of the inventive concept relate to electronic devices. More particularly, embodiments of the inventive concept relate to display devices and methods of manufacturing the display devices.

### DISCUSSION OF THE RELATED ART

As information technology has developed, the market for display devices has grown. Accordingly, the usage of flat panel displays (FPDs), e.g., liquid crystal displays (LCDs), organic light-emitting diodes (OLEDs), and plasma display panels (PDPs), has increased.

If a display panel has a flexible structure, the display device may be portable while in a state of being curved, folded, or rolled, and accordingly, portability is achieved even with bigger screen sizes.

### SUMMARY

An embodiment of the inventive concept provides a display device having a bending region resistant to stress.

An embodiment of the inventive concept provides a method of manufacturing a display device in which a bending region is uniformly filled with a filler.

A display device according to an embodiment of the inventive concept may include a display panel having a first region, a second region spaced apart from the first region, and a bending region connecting the first region and the second region, the bending region being bent along a bending axis to at least partially overlap the first region of the display panel and the second region of the display panel; a functional layer disposed at least in part where the first region of the display panel and the second region of the display panel partially overlap; a core arranged in a bending space defined by the bending region of the display panel and a side surface of the functional layer; and a filler filling the bending space to surround the core.

In an embodiment of the inventive concept, the bending space may be uniformly filled with the filler.

In an embodiment of the inventive concept, the core may include a light transmittance material.

In an embodiment of the inventive concept, the core may include at least one of a glass, polymethyl methacrylate (PMMA), and polystyrene (PS).

In an embodiment of the inventive concept, the core may include a thermally conductive material.

In an embodiment of the inventive concept, the core may include at least one of copper (Cu), aluminum (Al), and graphene.

In an embodiment of the inventive concept, the core may have a circular cone shape.

In an embodiment of the inventive concept, the core may have an oblique circular cone shape in which a vertex overlaps an edge of a base surface in a plan view.

In an embodiment of the inventive concept, the core may include a sealing portion and a conductive portion on the sealing portion, the conductive portion having a width less than or equal to a width of the sealing portion.

In an embodiment of the inventive concept, the sealing portion may have a circular cylinder shape.

In an embodiment of the inventive concept, the conductive portion may have a circular cylinder shape.

In an embodiment of the inventive concept, the conductive portion may have a coil spring shape.

In an embodiment of the inventive concept, the display device may further include a protective film between the display panel and the functional layer. A thickness of a portion of the protective film corresponding to the bending region may be less than a thickness of a portion of the protective film corresponding to the first region or the second region.

In an embodiment of the inventive concept, the core may contact the portion of the protective film corresponding to the bending region.

In an embodiment of the inventive concept, the protective film may include a protruding portion protruding toward the space. The core may be in contact with the protruding portion.

In an embodiment of the inventive concept, the sealing portion is made of a thermally conductive material, and the conductive portion conducts heat according to a shape of the conductive portion.

In an embodiment of the inventive concept, the first region has a first surface on which the protective film is disposed, and further includes a polarizing layer disposed on a second surface of the first region opposite to the first surface of the first region.

In an embodiment of the inventive concept, the display panel includes a substrate, a thin film transistor (TFT) disposed on the substrate, an organic light emitting diode (OLED) layer, and a thin film encapsulation layer disposed on the OLED layer and a buffer layer is in contact with the substrate and arranged between the TFT and the substrate.

A method of manufacturing a display device including a display panel having a first region, a second region spaced apart from the first region, and a bending region between the first region and the second region, the bending region being bent along a bending axis to at least partially overlap so that the first region of the display panel and the second region of the display panel; and a functional layer disposed at least in part where the first region and the second region overlap, the method including inserting a core in a bending space defined by the bending region of the display panel and a side surface of the functional layer; injecting a filler in the bending space in which the core is inserted; and hardening the filler.

In an embodiment of the inventive concept, the core may include a sealing portion and a conductive portion on the sealing portion, the conductive portion having a width less than or equal to a width of the sealing portion.

In an embodiment of the inventive concept, the core may be inserted inside the space in a direction from the sealing portion to the conductive portion.

In an embodiment of the inventive concept, the filler may be injected inside the space in a direction from the conductive portion to the sealing portion of the core.

In an embodiment of the inventive concept, hardening the filler may include irradiating an ultraviolet ray at the core.

In an embodiment of the inventive concept, hardening the filler may include supplying a heat to the core.

The display device according to an embodiment may include the filler uniformly filling the bending region. Accordingly, a resistance of the display device to stress may be increased.

In a method of manufacturing the display device according to embodiments of the inventive concept, the core may be inserted within the bending region to harden the filler with the ultraviolet ray or the heat. Accordingly, the filler may be uniformly filled inside the bending region.

In a method of manufacturing the display device according to embodiments of the inventive concept, the heat supplied to the core is initially supplied to the sealing portion and is transferred to the filler via the conductive portion.

### BRIEF DESCRIPTION OF THE DRAWINGS

Illustrative, non-limiting embodiments of the inventive concept will be more clearly understood by a person of ordinary skill in the art from the following detailed description taken in conjunction with the accompanying drawings.

FIG. 1A is a perspective view illustrating a display device according to an embodiment of the inventive concept in an unbent state.

FIG. 1B is a perspective view illustrating a display device in FIG. 1A in a bent state.

FIG. 2 is a cross-sectional view illustrating a display device according to an embodiment of the inventive concept.

FIGS. 3A, 3B, 3C, 3D, and 3E are perspective views illustrating respectively-shaped cores according to embodiments of the inventive concept.

FIG. 4 is a cross-sectional view illustrating a display panel according to an embodiment of the inventive concept.

FIG. 5 is a cross-sectional view illustrating a functional layer according to an embodiment of the inventive concept.

FIG. 6 is a cross-sectional view illustrating a display device according to an embodiment of the inventive concept.

FIG. 7 is a cross-sectional view illustrating a display device according to an embodiment of the inventive concept.

FIG. 8 is a flowchart illustrating a method of manufacturing a display device according to an embodiment of the inventive concept.

FIGS. 9A, 9B, 10A, 10B, 11A, 11B, 12, and 13 are cross-sectional views illustrating a method of manufacturing a display device according to an embodiment of the inventive concept in which:

FIGS. 9A and 9B show preparation of a bent display panel according to embodiments of the inventive concept;

FIGS. 10A and 10B show two views of a core inserted in a bending space according to embodiments of the inventive concept;

FIGS. 11A and 11B show the inserting of a filler around the core according to embodiments of the inventive concept;

FIG. 12 shows the filler being hardened by a UV process; and

FIG. 13 shows the filler being hardened according to a heating process.

### DETAILED DESCRIPTION OF EMBODIMENTS

Hereinafter, display devices and methods of manufacturing the display devices in accordance with embodiments of the inventive concept will be explained in detail with reference to the accompanying drawings.

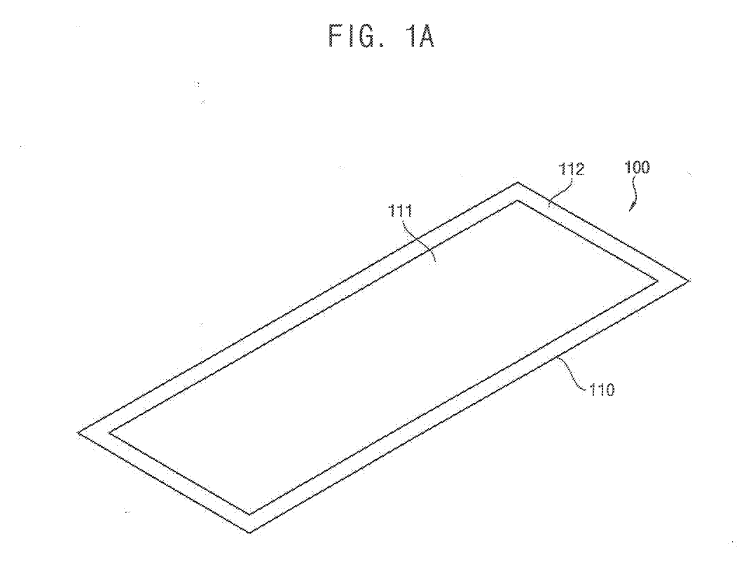

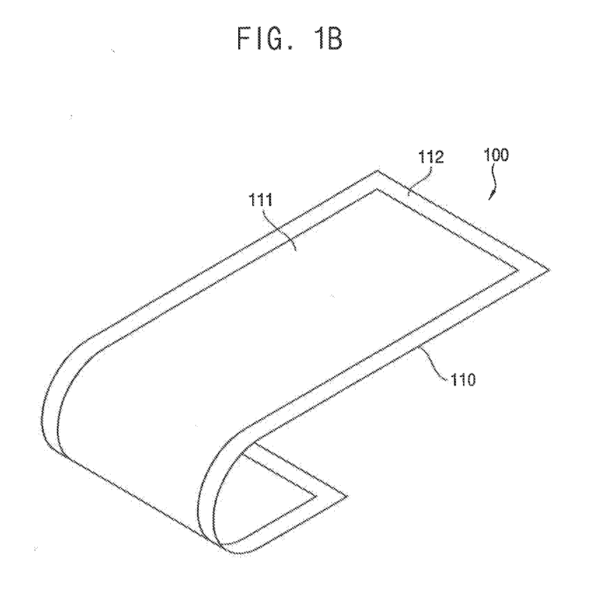

FIG. 1A is a perspective view illustrating a display device according to an embodiment of the inventive concept in an unbent state. FIG. 1B is a perspective view illustrating a display device in FIG. 1A in a bent state.

Referring to FIGS. 1A and 1B, a display device 100 according to an embodiment of the inventive concept may include a display panel 110. The display panel 110 may include a display region 111 for displaying an image and a non-display region 112 located outside the display region 111. The non-display region 112 may be arranged at least around partial of a periphery of the display region 111.

The display device 100 may include various layers such as a touch sensing layer, a polarizing layer 280, a cover window, etc., as well as the display panel 110.

The display device 100 may have a structure that can be deformed into various shapes such as an unbent shape (FIG. 1A), a bent shape, a rolled shape, a folded shape, or the like. FIG. 1B shows the display device having a bent shape.

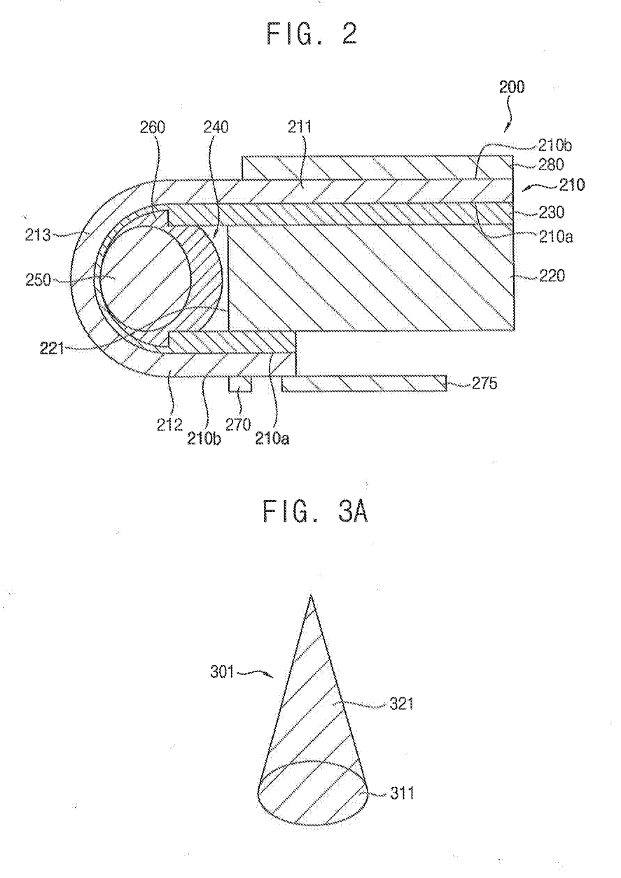

FIG. 2 is a cross-sectional view illustrating a display device according to an embodiment of the inventive concept.

Referring to FIG. 2, a display device 200 according to an embodiment of the inventive concept may include a display panel 210, a functional layer 220, a protective film 230, a core 250, a filler 260, a driving integrated circuit IC 270, a circuit board 275, and a polarizing layer 280.

In an embodiment of the inventive concept, the display panel 210 may be an organic light emitting display panel. However, embodiments of the inventive concept are not limited thereto, and the display panel 210 may be another display panel such as a liquid crystal display panel, a field emission display panel, an electronic paper display panel, or the like.

The display panel 210 may have a first surface 210a and a second surface 210b opposite to the first surface 210a. The display panel 210 may include a first region 211, a second region 212, and a bending region 213.

The first region 211 may be substantially flat, such as shown in FIG. 2. A plurality of pixels may be disposed in the first region 211 to display an image.

The second region 212 may be spaced apart from the first region 211. The second region 212 may be substantially flat. A plurality of pads may be disposed in the second region 212, and the pads may be connected to the pixels.

The bending region 213 may be located between the first region 211 and the second region 212. The bending region 213 may be bent along a bending axis. In an embodiment of the inventive concept, the first region 211 and the second region 212, which are located opposite sides of the bending region 213, may face each other. For example, the first surface 210a of the first region 211 and the first surface 210a of the second region 212 of the display panel 210 may face each other. As shown in FIG. 2, although a length of the first region 211 and the second region 212 may be unequal, in other embodiments of the inventive concept, the first region 211 and the second region 212 may be equal in length. Alternatively, a length of the second region 212 may be longer than a length of the first region 211.

Elements of the display panel 210 will now be described in detail below with reference to FIG. 2.

The functional layer 220 may be disposed between the first region 211 and the second region 212 of the display panel 210. The first surface 210a of the first region 211 and the first surface 210a of the second region 212 of the display panel 210 may face each other with the functional layer 220 in between.

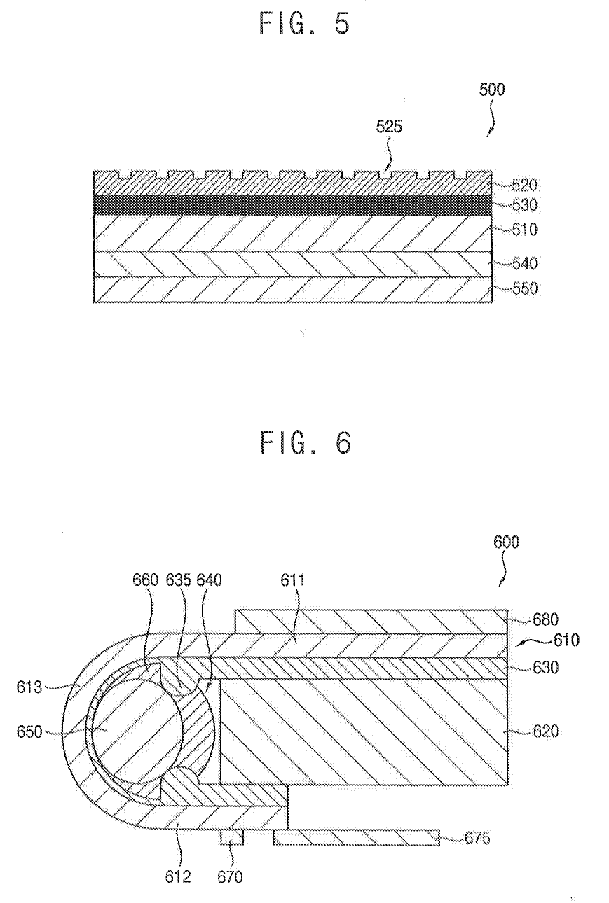

Elements of the functional layer 220 will be described in detail below with reference to FIG. 5.

The protective film 230 may be disposed between the display panel 210 and the functional layer 220. The protective film 230 may be disposed, for example, on the first surface 210a of the display panel 210. The protective film 230 may protect the first surface 210a of the display panel 210.

In an embodiment of the inventive concept, the protective film 230 may be disposed throughout the first region 211, the bending region 213, and the second region 212 on the first surface 210a of the display panel 210. A thickness of the protective film 230 corresponding to the bending region 213 may be less than a thickness of the protective film 230 corresponding to the first region 211 or the second region 212. The amount of thickness of the protective film 230 in the bending region 213 may be different in various embodiments of the inventive concept. For example, in one embodiment of the inventive concept, the thickness of the protective film 230 may be about 80-90% less in the bending region 213 than a thickness of the protective film 230 corresponding to the first region 211 and/or the second region 212. In another embodiment of the inventive concept, the thickness of the protective film 230 may be about 70%-80% less in the bending region 213. In another embodiment of the inventive concept, the thickness of the protective film 230 may be about 60%-70% less in the bending region 213. In another embodiment of the inventive concept, the thickness of the protective film 230 may be about 50%-60% less in the bending region 213. In still another embodiment of the inventive concept, the thickness of the protective film 230 may be about 30%-50% less in the bending region 213. In yet another embodiment of the inventive concept, the thickness of the protective film 230 may be about 15-30% less in the bending region 213. A person of ordinary skill in the art should understand and appreciate that the foregoing ranges are presented for illustrative purposes, and embodiments of the inventive concept are not limited to the ranges described above. For example, in another embodiment of the inventive concept, the protective film 230 may be disposed in the first region 211 and the second region 212 on the first surface 210a of the display panel 210, and may not be disposed in the bending region 213 on the first surface 210a of the display panel 210.

With continued reference to FIG. 2, the protective film 230 has a function of protecting the first surface 210a of the display panel 210. Thus, the protective film 230 may have some degree of strength. Accordingly, if the protective film 230 has low flexibility, when the bending region 213 of the display panel 210 is bent, exfoliation may occur between the display panel 210 and the protective film 230. However, in the display device 200 according to an embodiment of the inventive concept, the occurrence of the exfoliation may be effectively prevented or reduced because the thickness of the protective film 230 corresponding to the bending region 213 is less than the thickness of the protective film 230 corresponding to the first region 211 or the second region 212.

The polarizing layer 280 may be disposed on the second surface 210b of the first region 211 of the display panel 210. The polarizing layer 280 may prevent a reflection of an external light incident into the second surface 210b of the first region 211 of the display panel 210.

The driving IC 270 may be disposed on the second surface 210b of the second region 212 of the display panel 210. The driving IC 270 may be directly disposed on the second surface 210b of the display panel 210, or may be disposed on a flexible film that is disposed on the second surface 210b of the display panel 210. The driving IC 270 may be connected to the pads, and may transmit driving signals to the pixels through the pads.

The driving IC 270 may be electrically connected to the circuit board 275. The circuit board 275 may be a flexible printed circuit board (FPCB) 275. The circuit board 275 may be disposed on the second surface 210b of the second region 212 of the display panel 210.

The bending region 213 of the display panel 210 may be bent while passing by a side surface 221 of the functional layer 220. The side surface 221 of the functional layer 220 may face a concave portion of the bending region 213 of the display panel 210 at a predetermined distance. Accordingly, a space 240 between the bending region 213 of the display panel 210 and the side surface 221 of the functional layer 220 may be defined. Specifically, the space 240 may be surrounded by the protective film 230 and the side surface 221 of the functional layer 220. Hereinafter, the space 240 will be referred as a bending space 240.

The core 250 and the filler 260 may be disposed inside the bending space 240. An ultraviolet ray, a heat, or the like may transfer through the core 250 to the filler 260 during the hardening of the filler 260.

In an embodiment of the inventive concept, the core 250 may contact a portion of the protective film 230 corresponding to the bending region 213. The protective film 230 may have a predetermined adhesion. Therefore, when the core 250 contacts the protective film 230, a degree of fixation of the core 250 inside the bending space 240 may increase.

In an embodiment of the inventive concept, the core 250 may include a material that may be utilized for light transmittance. For some example non-limiting examples of a light transmittance material, the core 250 may include a glass, polymethyl methacrylate (PMMA), and/or polystyrene (PS). When the core 250 includes the light transmittance material, the hardening of the filler 260 with an ultraviolet ray may be easily performed.

In another embodiment of the inventive concept, the core 250 may include a thermally conductive material. For example, the core 250 may include copper (Cu), aluminum (Al), and/or graphene. When the core 250 includes the thermally conductive material, the hardening of the filler 260 with a heat may be easily performed.

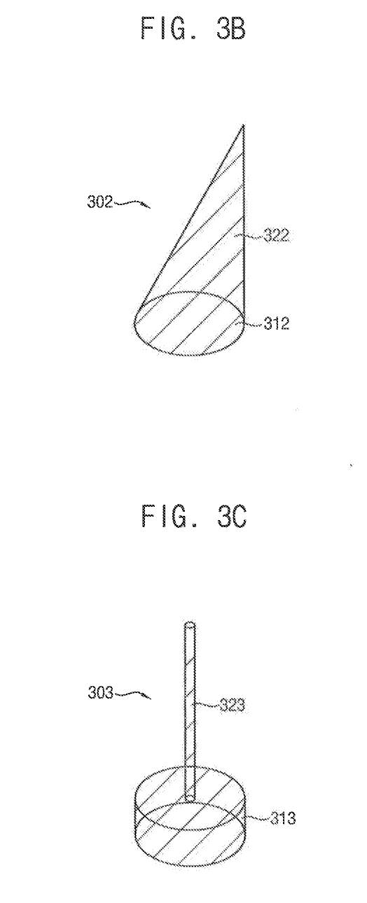

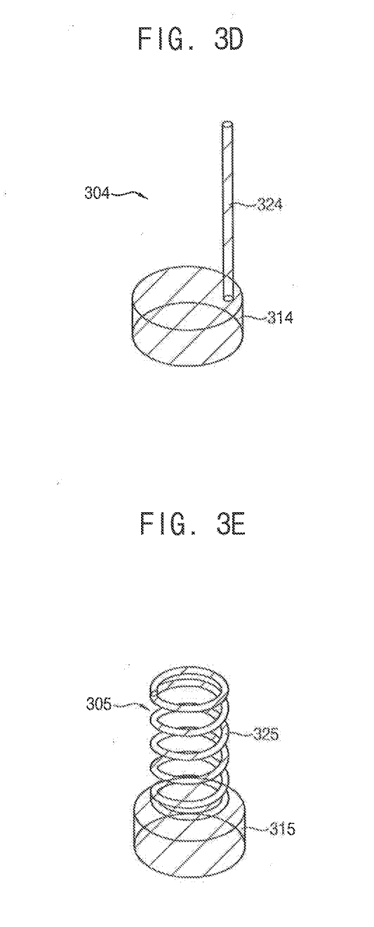

Elements and shapes of the core 250 will be described in detail below with reference to FIGS. 3A, 3B, 3C, 3D, and 3E. A person of ordinary skill in the art should understand and appreciate that the elements and shapes of the core 250 are presented for illustrative purposes, and the embodiments of the inventive concept are not limited to the core as shown in FIGS. 3A, 3B, 3C, 3D and 3E and described herein.

The filler 260 may fill at least some (e.g., partially fills), or all of the bending space 240 that is surrounding the core 250. The filler 260 may increase the resistance of the display device 200 against stress applied from the outside. The filler 260 may include a resin.

In an embodiment of the inventive concept, the filler 260 may partially fill the bending space 240. For example, a portion of the bending space 240 between the filler 260 and the side surface 221 of the functional layer 220 may not be filled by the filler 260.

FIGS. 3A, 3B, 3C, 3D, and 3E are perspective views illustrating cores according to embodiments of the inventive concept.

Referring to FIG. 3A, a core 301 may include a sealing portion 311 and a conductive portion 321 disposed on the sealing portion 311.

In an embodiment of the inventive concept, a width of the conductive portion 321 may be less than or equal to a width of the sealing portion 311 (see FIG. 3A). The sealing portion 311 may prevent the filler 260 in FIG. 2 from leaking to the outside during injecting the filler 260. The core 301 may be inserted in a direction from the sealing portion 311 to the conductive portion 321 when inserting the core 301. Accordingly, a leakage of the filler 260 may be easily prevented when the width of the sealing portion 311 is relatively large, and the core 301 may be easily inserted in the bending region 213 when the width of the conductive portion 321 is relatively small. In an embodiment of the inventive concept, a cross-sectional area of the conductive portion 321 may be less than or equal to a cross-sectional area of the sealing portion 311.

In an embodiment of the inventive concept, the core 301 may have a circular cone shape. For example, the core 301 may have a right circular cone shape in which a vertex overlaps a center of a base surface in a plan view. In this case, the sealing portion 311 may correspond to the base surface of the circular cone shape, and the conductive portion 321 may correspond to a lateral surface of the circular cone shape.

Referring to FIG. 3B, in an embodiment of the inventive concept, a core 302 may have an oblique circular cone shape. For example, the core 302 may have an oblique circular cone shape in which a vertex overlaps an edge of a base surface in a plan view. In this case, a sealing portion 312 may correspond to the base surface of the circular cone shape, and a conductive portion 322 may correspond to a lateral surface of the circular cone shape.

The core 302 may be more easily disposed inside the bending space 240 in FIG. 2 because the core 302 has the oblique circular cone shape in which the vertex overlaps the edge of the base surface. For example, the lateral surface perpendicular to the base surface of the core 302 may contact an inner wall of the bending space 240, so that the core 302 may be easily fixed inside the bending space 240.

Referring to FIG. 3C, in an embodiment of the inventive concept, a core 303 may include a sealing portion 313 and a conductive portion 323 which have circular cylinder shapes, respectively. A diameter of a base surface of the conductive portion 323 may be less than or equal to a diameter of a base surface of the sealing portion 313.

In an embodiment of the inventive concept, a center of the base surface of the sealing portion 313 may overlap a center of the base surface of the conductive portion 323 in a plan view.

Referring to FIG. 3D, in an embodiment of the inventive concept, a center of a base surface of a sealing portion 314 of a core 304 may not overlap a center of a base surface of a conductive portion 324 of the core 304 in a plan view. A person of ordinary skill in the art can see that the conductive portion 324 is not centered with the base surface of the sealing portion 314. For example, an edge of the base surface of the conductive portion 324 may be adjacent to an edge of the base surface of the sealing portion 314.

The core 304 may be more easily disposed inside the bending space 240, because the edge of the base surface of the conductive portion 324 is adjacent to the edge of the base surface of the sealing portion 314. For example, a lateral surface of the conductive portion 324 of the core 304 may contact an inner wall of the bending space 240, so that the core 304 may be easily fixed inside the bending space 240.

Referring to FIG. 3E, in an embodiment of the inventive concept, a core 305 may include a sealing portion 315 having a circular cylinder shape and a conductive portion 325 having a coil spring shape. With a conductive portion 325 has the coil spring shape, in this embodiment of the inventive concept, the filler provided in the bending shape region may be arranged around the coils of the conductive portion 325. This type of construction may provide for increased resistance of the display device 200 against external stresses.

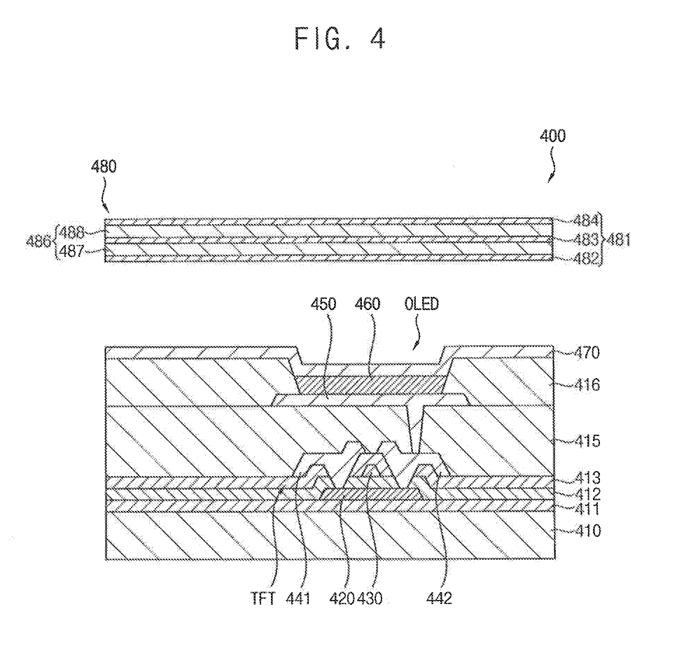

FIG. 4 is a cross-sectional view illustrating a display panel 400 according to an embodiment of the inventive concept. A person of ordinary skill in the art should understand and appreciate that the display panel 400 shown in FIG. 4 is provided for illustrative purposes, and embodiments of the inventive concept and the appended claims are not limited to the illustration of FIG. 4.

Referring to FIG. 4, a display panel 400 according to an embodiment of the inventive concept may include a substrate 410, a thin film transistor TFT, an organic light emitting diode OLED, and a thin film encapsulation layer 480.

The substrate 410 may be, for example, a flexible glass substrate or a flexible plastic substrate. The substrate 410 may be transparent, translucent, or opaque.

A buffer layer 411 may be disposed on the substrate 410. The buffer layer 411 may substantially cover an upper surface of the substrate 410. For example, the buffer layer 411 may cover less than an entirety of the upper surface of the substrate 410 in an embodiment of the inventive concept. However, in another embodiment of the inventive concept, the buffer layer 411 may cover an entirety of the upper surface of the substrate 410. The buffer layer 411 may be formed of an inorganic material or an organic material. The buffer layer 411 may have a single-layered structure or a multi-layered structure.

The thin film transistor TFT may be disposed on the buffer layer 411. In an embodiment of the inventive concept, the thin film transistor TFT may have a top gate transistor structure, however, the thin film transistor TFT may have other transistor structure such as a bottom gate transistor structures or the like.

An active pattern 420 may be disposed on the buffer layer 411. The active pattern 420 may include a source region and a drain region which are doped with N-type impurities or P-type impurities. A channel region that is not doped with impurities may be located between the source region and the drain region. The active pattern 420 may include an organic semiconductor, an inorganic semiconductor or polycrystalline silicon. In an embodiment of the inventive concept, the active pattern 420 may include an oxide semiconductor.

With continued reference to FIG. 4, a gate insulation layer 412 may be disposed on the active pattern 420. The gate insulation layer 412 may be formed of an inorganic material. The gate insulation layer 412 may have a single-layered structure or a multi-layered structure.

A gate electrode 430 may be disposed on the gate insulation layer 412. The gate electrode 430 may be formed of a metal having great conductivity. The gate electrode 430 may have a single-layered structure or a multi-layered structure.

An insulation interlayer 413 may be disposed on the gate electrode 430. The insulation interlayer 413 may be formed of an inorganic material, or an organic material.

A source electrode 441 and a drain electrode 442 may be disposed on the insulation interlayer 413. Specifically, contact holes may be formed by removing portions of the gate insulation layer 412 and the insulation interlayer 413, and the source electrode 441 and the drain electrode 442 may be electrically connected to the source region and the drain region of the active pattern 420, respectively.

A planarization layer 415 may be disposed on the source electrode 441 and the drain electrode 442. The planarization layer 415 may be formed of an inorganic material or an organic material.

The organic light emitting diode OLED may be disposed on the planarization layer 415. The organic light emitting diode OLED may be electrically connected to the thin film transistor TFT. The organic light emitting diode OLED may include a first electrode 450, an organic light emitting layer 460, and a second electrode 470.

The first electrode 450 may be disposed on the planarization layer 415. The first electrode 450 may function as an anode, and may be formed of various conductive material. The first electrode 450 may include a transparent layer or a reflective layer.

A pixel defining layer 416 may be disposed on the planarization layer 415. The pixel defining layer 416 may cover a portion of the first electrode 450. Specifically, the pixel defining layer 416 may surround an edge of the first electrode 450 to define an emission region of each pixel. The first electrode 450 may be patterned per each pixel.

The pixel defining layer 416 may be formed of an inorganic material or an organic material. The pixel defining layer 416 may have a single-layered structure or a multi-layered structure.

The organic light emitting layer 460 may be disposed on a region on the first electrode 450 exposed by etching a portion of the pixel defining layer 416. The organic light emitting layer 460 may be formed by various disposition processes.

In an embodiment of the inventive concept, a hole injection layer (HIL) and/or a hole transport layer (HTL) may be additionally disposed between the first electrode 450 and the organic light emitting layer 460, and an electron transport layer (ETL) and/or an electron injection layer (EIL) may be additionally disposed on the organic light emitting layer 460.

The second electrode 470 may be disposed on the organic light emitting layer 460. The second electrode 470 may function as a cathode, and may be formed various conductive material. The second electrode 470 may include a transparent layer or a reflective layer.

The thin film encapsulation layer 480 may be disposed on the organic light emitting diode OLED. The thin film encapsulation layer 480 may include an inorganic layer 481 and an organic layer 486 which are alternately layered. For example, the inorganic layer 481 may include a first inorganic layer 482, a second inorganic layer 483 disposed on the first inorganic layer 482, and a third inorganic layer 484 disposed on the second inorganic layer 483. Further, the organic layer 486 may include a first organic layer 487 disposed between the first inorganic layer 482 and the second inorganic layer 483, and a second organic layer 488 disposed between the second inorganic layer 483 and the third inorganic layer 484.

FIG. 5 is a cross-sectional view illustrating a functional layer 500 according to an embodiment of the inventive concept.

Referring to FIG. 5, a functional layer 500 according to an embodiment of the inventive concept may include a cushion layer 510, an embossing layer 520, a black layer 530, a graphite layer 540, and a heat dissipation layer 550.

The cushion layer 510 may be disposed under the display panel 210 in FIG. 2, and may reduce an impact that may otherwise be applied to the display panel 210. The cushion layer 510 may include a polymer such as polypropylene (PP) or polyethylene (PE). In an embodiment of the inventive concept, the cushion layer 510 may include any material that has a density of about 0.5 g/cm³ or more. The cushion layer 510 may be formed as a foam or gel. In an embodiment of the inventive concept, the cushion layer 510 may include a material having high elastic force, for example, rubber.

The embossing layer 520 may be disposed between the display panel 210 and the cushion layer 510. The embossing layer 520 may have an adhesive capability. The embossing layer 520 may include, or define, a plurality of air discharge holes 525 on a surface thereof facing the display panel 520.

The black layer 530 may be disposed between the cushion layer 510 and the embossing layer 520 to prevent exposure of constituting parts such as the driving IC 270 in FIG. 2, the circuit board 275 in FIG. 2, and the like. The black layer 530 may include a black insulating material.

The graphite layer 540 may be disposed under the cushion layer 510. The graphite layer 510 may dissipate heat.

The heat dissipation layer 550 may be disposed under the graphite layer 540. The heat dissipation layer 550 may include a metal layer including, for example, copper. The heat dissipation layer 550 may emit heat that has been generated by the display panel 210 toward outside.

FIG. 6 is a cross-sectional view illustrating a display device according to an embodiment of the inventive concept.

Referring to FIG. 6, a display device 600 according to an embodiment of the inventive concept may include a display panel 610, a functional layer 620, a protective film 630, a core 650, a filler 660, a driving IC 670, a circuit board 675, and a polarizing layer 680. Descriptions of elements of the display device 600 according to an embodiment of the inventive concept with reference to FIG. 6, which are substantially the same as or similar to those of the display device 200 according to an embodiment of the inventive concept with reference to FIG. 2, will not be repeated.

The core 650 and the filler 660 may be disposed inside the bending space 640. The core 650 may transfer an ultraviolet ray, a heat, or the like to the filler 660 during hardening the filler 660.

In an embodiment of the inventive concept, the core 650 may contact a portion of the protective film 630 corresponding to the bending region 613. The protective film 630 may have a predetermined adhesion. Therefore, when the core 650 contacts the protective film 630, a degree of fixation of the core 650 inside the bending space 640 may increase.

In an embodiment of the inventive concept, the protective film 630 may include a protruding portion 635 protruding toward the bending space 640. Specifically, the protruding portion 635 may be formed at an end of the protective film 630 corresponding to the first region 611 adjacent to the protective film 630 corresponding to the bending region 613 and/or at an end of the protective film 630 corresponding to the second region 612 adjacent to the protective film 630 corresponding to the bending region 613. The protruding portion 635 may be formed when materials constituting the protective film 630 are deposited during the formation of the protective film 630.

In an embodiment of the inventive concept, the core 650 may contact the protruding portion 635 of the protective film 630. The protective film 630 may have a predetermined adhesion. Accordingly, when the core 650 contacts the protruding portion 635 of the protective film 630, a degree of fixation of the core 650 inside the bending space 640 may further increase.

FIG. 7 is a cross-sectional view illustrating a display device according to an embodiment of the inventive concept.

Referring to FIG. 7, a display device 700 according to an embodiment of the inventive concept may include a display panel 710, a functional layer 720, a protective film 730, a core 750, a filler 760, a driving IC 770, a circuit board 775, and a polarizing layer 780. Descriptions on elements of the display device 700 according to an embodiment of the inventive concept with reference to FIG. 7, which are substantially the same as or similar to those of the display device 200 according to an embodiment of the inventive concept with reference to FIG. 2, will not be repeated.

The core 750 and the filler 760 may be disposed inside the bending space 740. The core 750 may transfer an ultraviolet ray, a heat, or the like to the filler 760 during hardening the filler 760.

The filler 760 may fill the bending space 740 while surrounding the core 750. The filler 760 may increase the resistance of the display device 700 against stress applied from outside. The filler 760 may include a resin.

In an embodiment of the inventive concept, the filler 760 may substantially entirely fill the bending space 740. For example, the filler 760 may surround the core 750 and completely fill the bending space 740. Therefore, the resistance of the display device 700 against stress applied from outside may further increase.

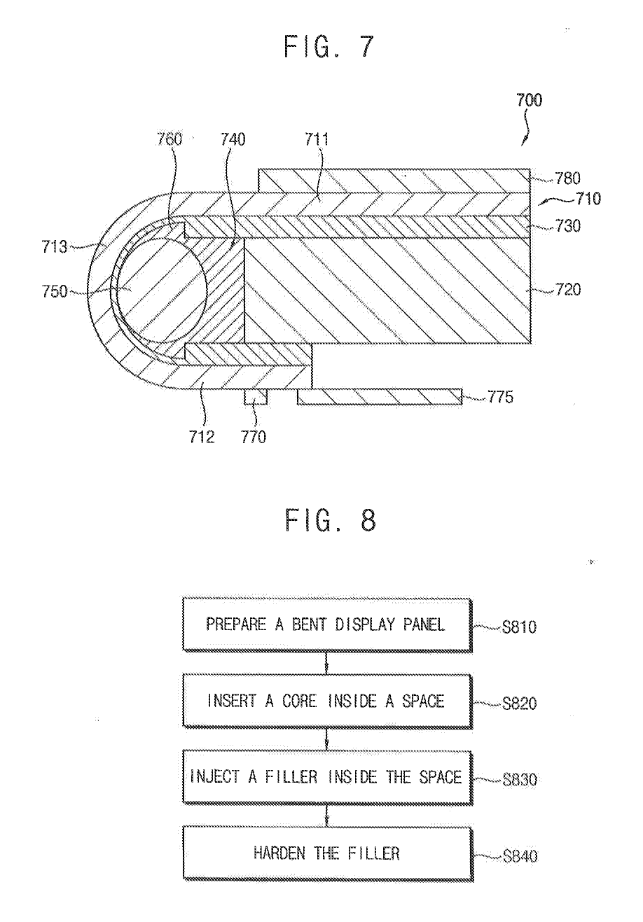

FIG. 8 is a flowchart illustrating a method of manufacturing a display device according to an embodiment of the inventive concept.

Referring to FIG. 8, a method of manufacturing a display device according to an embodiment of the inventive concept may include preparing a bent display panel S810, inserting a core 750 inside a space S820, injecting a filler 760 inside the space S830, and hardening the filler S840.

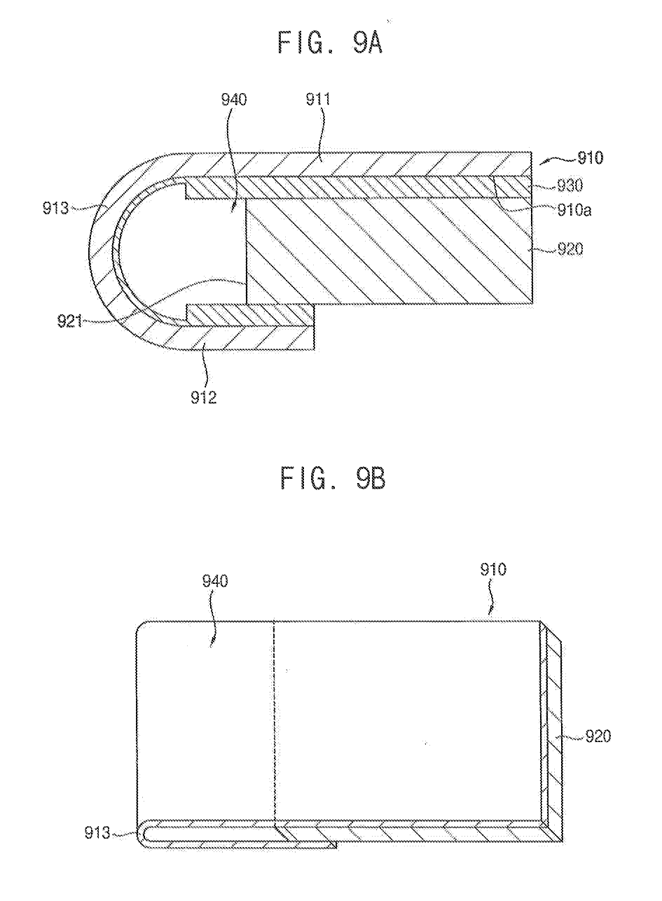

FIGS. 9A, 9B, 10A, 10B, 11A, 11B, 12, and 13 are cross-sectional views illustrating a method of manufacturing a display device according to an embodiment of the inventive concept.

Referring to FIGS. 8, 9A, and 9B, a bent display panel 910 may be prepared (S810). First, a protective film 930 and a functional layer 920 may be sequentially attached to a first surface 910a of a first region 911 of the bent display panel 910. In an embodiment of the inventive concept, after the protective film 930 is attached to the first surface 910a of the bent display panel 910, a portion of the protective film 930 corresponding to a bending region 913 may be partially or completely removed.

Then, the bending region 913 of the bent display panel 910 may be bent while passing by a side surface 921 of the functional layer 920. Accordingly, a portion of the protective film 930 corresponding to a second region 912 may contact a lower surface of the functional layer 920, and the first region 911 and the second region 912 of the bent display panel 910 may face each other with the functional layer 920 in between.

The side surface 921 of the functional layer 920 may face a concave portion of the bending region 913 of the bent display panel 910 at a predetermined distance. Accordingly, a bending space 940 between the bending region 913 of the bent display panel 910 and the side surface 921 of the functional layer 920 may be defined. In other words, the bending space 940 may be surrounded by the protective film 930 and the side surface 921 of the functional layer 920.

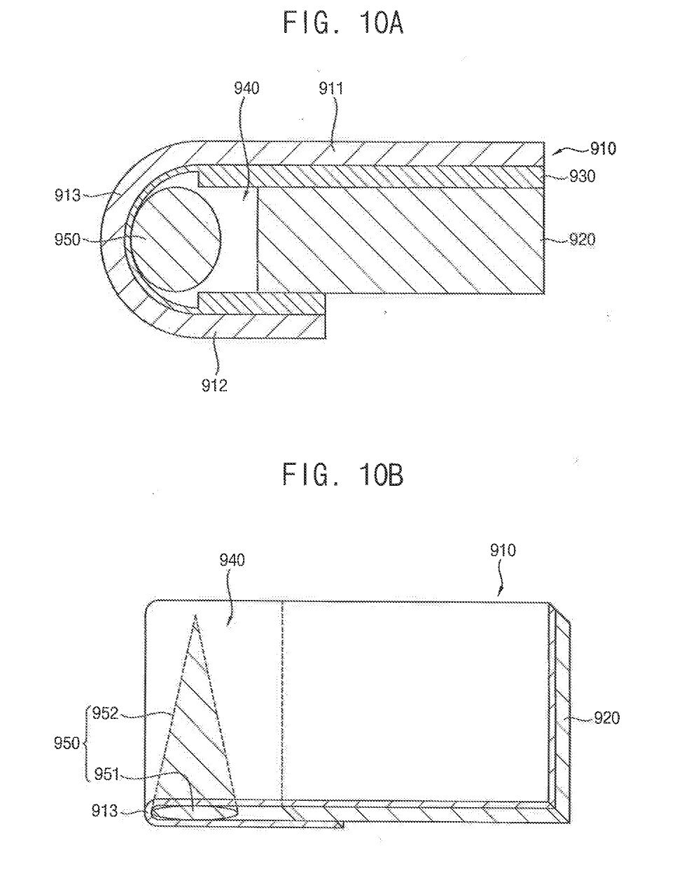

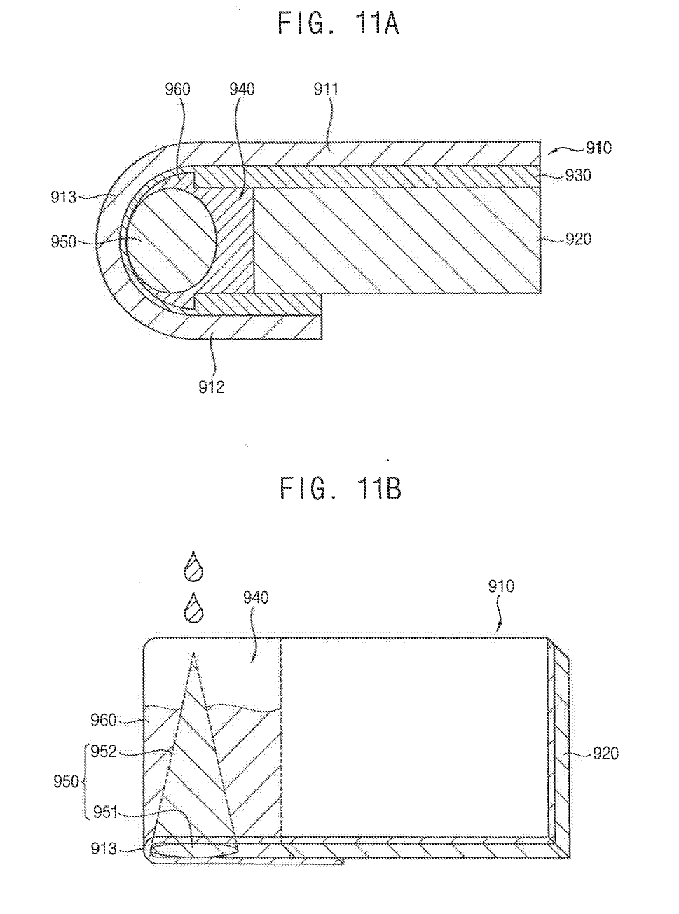

Referring to FIGS. 8, 10A, and 10B, a core 950 may be inserted inside the space 940 (S820). The core 950 may transfer an ultraviolet ray, a heat, or the like to a filler 960 in FIG. 11A during the following process in which the filler 960 is hardened.

The core 950 may include a sealing portion 951 and a conductive portion 952 disposed on the sealing portion 951. A width and/or an area of the conductive portion 952 may be less than a width and/or an area of the sealing portion 951.

In an embodiment of the inventive concept, the core 950 may be inserted inside the bending space 940 in a direction from the sealing portion 951 to the conductive portion 952. The conductive portion 952 may have a relatively small width (or area), so that the core 950 may be easily inserted within the bending space 940.

Referring to FIGS. 8, 11A, and 11B, the filler 960 may be injected into the space 940 (S830). The filler 960 may fill the bending space 940, so that resistance of the display device against stress applied from outside. In an embodiment of the inventive concept, a liquefied filler 960 having fluidity may be injected within the bending space 940. The filler 960 may include a resin.

In an embodiment of the inventive concept, the filler 960 may be injected inside the bending space 940 in a direction from the conductive portion 952 to the sealing portion 951 of the core 950. The conductive portion 952 may have a relatively small width (or area), so that the filler 960 may be easily injected within the bending space 940. Further, the sealing portion 951 may have a relatively large width (or area), so that a leakage of the filler 960 to the outside may be easily prevented.

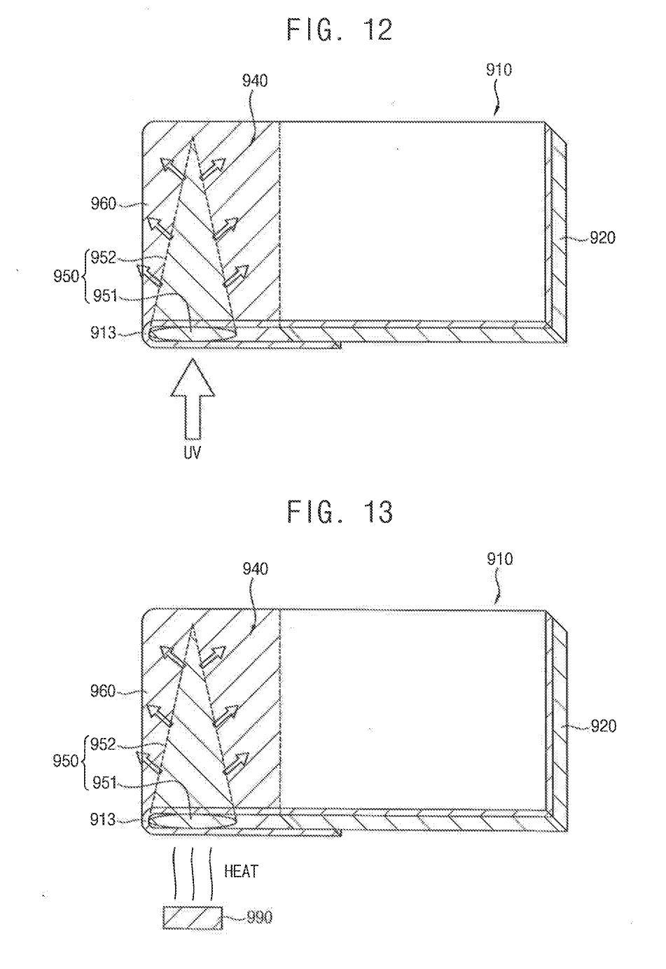

Referring to FIGS. 8 and 12, the filler 960 may be hardened (S840). In an embodiment of the inventive concept, an ultraviolet ray (UV) may be irradiated at the core 950 to harden the filler 960. The UV irradiated at the core 950 may be diffused and transferred to the filler 960, and the filler 960 filling the bending space 940 may be light-hardened by the UV.

When the filler 960 is hardened by the UV, the core 950 may include a light transmittance material. For example, the core 950 may include a glass, polymethyl methacrylate (PMMA), and/or polystyrene (PS).

In an embodiment of the inventive concept, the UV may be irradiated at the sealing portion 951 of the core 950. In this case, the UV irradiated at the sealing portion 951 may be transferred to the conductive portion 952, and then, the UV may be diffused according to a shape of the conductive portion 952.

Referring to FIG. 13, in an embodiment of the inventive concept, a heat may be supplied to the core 950 to harden the filler 960. The heat supplied to the core 950 may be transferred to the filler 960, and the filler 960 filling the bending space 940 may be thermal-hardened by the heat.

When the filler 960 is hardened by the heat, the core 950 may include a thermally conductive material. For example, the core 950 may include copper (Cu), aluminum (Al), and/or graphene.

In an embodiment of the inventive concept, the heat may be supplied to the sealing portion 951 of the core 950. For example, a thermal source 990 may be disposed adjacent to the sealing portion 951 of the core 950. In this case, the heat supplied to the sealing portion 951 may be transferred to the conductive portion 952, and then, the heat may be conducted according to a shape of the conductive portion 952.

The display device according to the embodiments of the inventive concept may be applied to a display device included in a computer, a notebook, a mobile phone, a smartphone, a smart pad, a PMP, a PDA, an MP3 player, or the like.

Although the display devices and the method of manufacturing the display devices according to the embodiments of the inventive concept have been described with reference to the drawings, the illustrated embodiments of the inventive concept are examples, and may be modified and changed by a person having ordinary knowledge in the relevant technical field without departing from the technical spirit of the embodiments of the inventive concept described in the appended claims.

What is claimed is:

1. A display device, comprising:
a display panel having a first region, a second region spaced apart from the first region, and a bending region connecting the first region and the second region, the bending region being bent along a bending axis to at least partially overlap the first region of the display panel and the second region of the display panel;
a functional layer disposed at least in part where the first region of the display panel and the second region of the display panel partially overlap;
a core arranged in a bending space defined by the bending region of the display panel and a side surface of the functional layer; and
a filler filling the bending space to surround the core.

2. The display device of claim 1, wherein the bending space is uniformly filled with the filler.

3. The display device of claim 1, wherein the core comprises a light transmittance material.

4. The display device of claim 1, wherein the core comprises a thermally conductive material.

5. The display device of claim 1, wherein the core has a circular cone shape.

6. The display device of claim 5, wherein the core has an oblique circular cone shape in which a vertex overlaps an edge of a base surface in a plan view.

7. The display device of claim 1, wherein the core comprises a sealing portion and a conductive portion arranged on the sealing portion, the conductive portion having a width less than or equal to a width of the sealing portion.

8. The display device of claim 7, wherein the sealing portion has a circular cylinder shape, and
wherein the conductive portion has a circular cylinder shape.

9. The display device of claim 7, wherein the sealing portion has a circular cylinder shape, and
wherein the conductive portion has a coil spring shape.

10. The display device of claim 1, further comprising a protective film disposed between the display panel and the functional layer,
wherein a thickness of a portion of the protective film corresponding to the bending region is less than a thickness of a portion of the protective film corresponding to the first region or the second region, and
wherein the first region has a first surface on which the protective film is disposed, and further comprising a polarizing layer disposed on a second surface of the first region opposite to the first surface of the first region.

11. The display device of claim 10, wherein the core is in contact with the portion of the protective film corresponding to the bending region.

12. The display device of claim 10, wherein the protective film comprises a protruding portion protruding toward the bending space, and
wherein the core is in contact with the protruding portion.

13. The display device according to claim 1, wherein the display panel includes a substrate, a thin film transistor (TFT) disposed on the substrate, an organic light emitting diode (OLED) layer, and a thin film encapsulation layer disposed on the OLED layer, and
a buffer layer in contact with the substrate and arranged between the TFT and the substrate.

14. A method of manufacturing a display device including a display panel having a first region, a second region spaced apart from the first region, and a bending region between the first region and the second region, the bending region being bent along a bending axis to at least partially overlap so that the first region of the display panel and the second region of the display panel; and a functional layer disposed at least in part where the first region and the second region overlap, the method comprising:
inserting a core in a bending space defined by the bending region of the display panel and a side surface of the functional layer;
injecting a filler in the bending space in which the core is inserted; and
hardening the filler.

15. The method of claim 14, wherein the core comprises a sealing portion and a conductive portion disposed on the sealing portion, the conductive portion having a width less than or equal to a width of the sealing portion.

16. The method of claim 15, wherein the core is inserted in the bending space in a direction from the sealing portion to the conductive portion.

17. The method of claim 15, wherein the filler is injected in the bending space in a direction from the conductive portion to the sealing portion of the core.

18. The method of claim 14, wherein hardening the filler comprises irradiating an ultraviolet ray at the core.

19. The method of claim 14, wherein hardening the filler comprises supplying a heat to the core that is transferred to the filler.

20. The method of claim 19, wherein the heat is initially supplied to a sealing portion.
